(19) United States
(12) Patent Application Publication
(10) Pub. No.: US 2022/0205690 A1
(43) Pub. Date: Jun. 30, 2022

(54) TEMPERATURE CONTROL OF THERMOELECTRIC COOLING FOR LIQUID COOLING SYSTEMS

(71) Applicant: Hewlett-Packard Development Company, L.P., Spring, TX (US)

(72) Inventor: Fu-Yi Chen, Taipei City (TW)

(73) Assignee: Hewlett-Packard Development Company, L.P., Spring, TX (US)

(21) Appl. No.: 17/606,074

(22) PCT Filed: Jul. 31, 2019
(86) PCT No.: PCT/US2019/044280

§ 371 Date: Oct. 25, 2021

(51) Int. Cl. F25B 21/02; H05K 7/20; H01L 35/30

(52) U.S. Cl. CPC F25B 21/02; H01L 35/30; H05K 7/20272; H05K 7/20263

(57) ABSTRACT

A device to thermoelectrically cool a cooling fluid is described. The device includes a cooling fluid circulation system to circulate a cooling fluid which cools a hardware component of a computer. The device further includes a thermoelectric cooling unit to cool the cooling fluid. The device further includes a controller to execute temperature control instructions to control the thermoelectric cooling unit to cool the cooling fluid to a cooling temperature not lower than ambient temperature to reduce the risk of water condensation.

### BACKGROUND

Computers, including desktop computers, laptop computers, and server computers, will typically contain a computer hardware component that generates significant heat at high levels of performance. Notable examples of computer hardware components that generate significant heat include central processing units (CPUs) and graphics processing units (CPUs). CPUs and GPUs are typically kept cool with cooling fans or liquid cooling systems.

A liquid cooling system will generally have greater capability to cool a CPU or a GPU than a cooling fan. A liquid cooling system operates by circulating a cooling fluid between a computer hardware component, such as a CPU or GPU, to extract heat from the component, and a heat exchanger, which vents heat from the cooling fluid outside the computer.

### BRIEF DESCRIPTION OF THE DRAWINGS

FIG. 1 is a schematic diagram of an example device to thermoelectrically cool a cooling fluid of a cooling fluid circulation system.

FIG. 2 is a schematic diagram of an example liquid cooling system that includes a thermoelectric cooling unit to cool a cooling fluid.

FIG. 3 is a flowchart of an example method for cooling a cooling fluid of a liquid cooling system with a thermoelectric cooling unit.

FIG. 4 is a schematic diagram of an example liquid cooling system depicted inside a housing of a computer including a heat exchanger and thermoelectric cooling unit which each vent heat outside the computer.

FIG. 5 is a schematic diagram of an example liquid cooling system depicted inside a housing of a computer including a thermoelectric cooling unit integrated into a heat exchanger which vents heat outside the computer.

### DETAILED DESCRIPTION

A liquid cooling system for a computer includes a cooling fluid circulation system that transfers heat from a computer hardware component to a cooling fluid and vents the heat from the cooling fluid through a heat exchanger to ambient air outside the computer. Although a liquid cooling system may effectively transfer heat from the computer hardware component to the cooling fluid at the point of contact with the computer hardware component, the liquid cooling system may be limited at effectively transferring heat from the cooling fluid to ambient air through the heat exchanger. Regardless of the size and design of the heat exchanger, the insulative properties of air may limit the temperature to which the cooling fluid is cooled by the heat exchanger. As a result, the cooling fluid may leave the heat exchanger at a temperature significantly higher than ambient temperature.

The capability of the liquid cooling system to cool the computer hardware component may be improved if the cooling fluid is cooled to a lower temperature. The cooling fluid may be cooled to a lower temperature using a thermoelectric cooling unit. The thermoelectric cooling unit may be included in the cooling fluid circulation system to provide additional cooling to the cooling fluid either before or after passing through the ambient air heat exchanger. Thus, the cooling fluid may be cooled by both an ambient air heat exchanger and a thermoelectric cooling unit.

However, using a thermoelectric cooling unit to further cool the cooling fluid raises risks associated with water condensation. That is, if the thermoelectric cooling unit provides too much cooling, water condensation may form on any surface that is cooled below ambient temperature, such as a surface of the tubing through which the cooling fluid flows or a surface of the thermoelectric cooling unit itself. Water condensation inside a computer poses a risk of damaging computer hardware components.

A liquid cooling system is provided herein which includes a thermoelectric cooling unit to provide additional cooling to the cooling fluid while the thermoelectric cooling unit is controlled to cool the cooling fluid to a temperature at or near ambient temperature, but no lower than ambient temperature. Thus, additional cooling may be provided without the risks associated with water condensation, and computer hardware components may be operated at higher levels of performance at cooler temperatures.

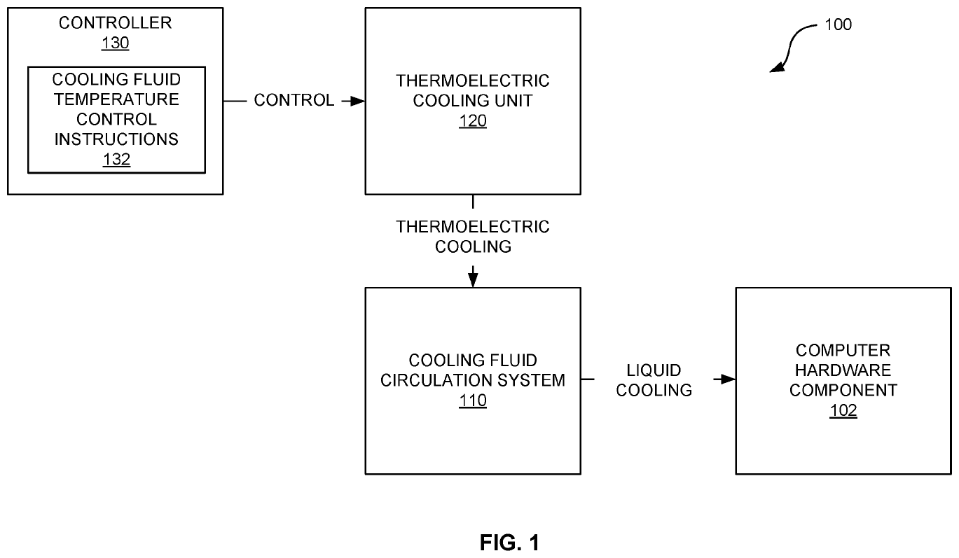

FIG. 1 is a schematic diagram of an example device 100 to thermoelectrically cool a cooling fluid of a cooling fluid circulation system 110. The device 100 includes the cooling fluid circulation system 110, which is able to circulate a cooling fluid to cool a computer hardware component 102 of a computer. The cooling fluid circulation system 110 may include a thermal contact unit to make thermal contact with the computer hardware component, a pump and tubing to circulate the cooling fluid to the thermal contact unit, and a heat exchanger to cool the cooling fluid with ambient air.

The computer may be a desktop computer, laptop computer, server computer, or any other computing device which includes a computer hardware component that generates heat and which may employ a liquid cooling system to cool the computer hardware component. The computer hardware component 102 may include a central processing unit (CPU), graphics processing unit (GPU), or another component which generates heat while in operation.

The device 100 further includes a thermoelectric cooling device or unit 120 to cool the cooling fluid. The thermoelectric cooling unit 120 is controlled by a controller 130. The controller 130 executes cooling fluid temperature control instructions 132 to control the thermoelectric cooling unit 120 to cool the cooling fluid to a cooling temperature not lower than ambient temperature. The cooling fluid temperature control instructions 132 is embodied in a non-transitory machine-readable storage medium executable by the controller 130. The controller 130 includes a processor capable of executing the cooling fluid temperature control instructions 132. The controller 130 may be located on the thermoelectric cooling unit 120 or elsewhere in the device 100.

The device 100 may include an ambient temperature sensor to measure the temperature of ambient air. Further, the device 100 may include a cooling fluid temperature sensor to measure the temperature of the cooling fluid. These temperature sensors may provide temperature readings to the controller 130 so that the controller 130 can determine whether to turn on, turn off, throttle, increase the power to, decrease the power to, or otherwise control the thermoelectric cooling unit 120 to control the temperature to which the cooling fluid is cooled.

The cooling fluid circulation system 110 may include a heat exchanger to vent heat from the cooling fluid outside the computer. The cooling fluid circulation system 110 may circulate the cooling fluid from the heat exchanger to the thermoelectric cooling unit 120 for cooling prior to circulation to the computer hardware component 102. Thus, the thermoelectric cooling unit 120 provides an additional cooling boost to the cooling fluid after it passes through the heat exchanger to ensure that the cooling fluid reaches a temperature closer to ambient temperature. With the cooling fluid passing through the heat exchanger before passing through the thermoelectric cooling unit 120, the load on the thermoelectric cooling unit 120 is reduced.

In some examples, for convenience of installation, the thermoelectric cooling unit 120 may be fixed to the heat exchanger or integrated with the heat exchanger. In such examples, the thermoelectric cooling unit 120 may vent heat through the heat exchanger. In other examples, the thermoelectric cooling unit 120 may be separate from the heat exchanger and may vent heat separately. In such examples, the thermoelectric cooling unit 120 may be connected to the heat exchanger by tubing to transport the cooling fluid.

The thermoelectric cooling unit 120 may include an inlet to receive cooling fluid and an outlet through which cooled cooling fluid leaves the thermoelectric cooling unit 120 after cooling. The cooling fluid temperature sensor may include an outlet temperature sensor located at the outlet to measure an outlet temperature of the cooling fluid. The temperature of the cooling fluid leaving the thermoelectric cooling unit 120 may be the lowest temperature the cooling fluid reaches, and thus may be an appropriate place to measure the temperature of the cooling fluid for controlling the thermoelectric cooling unit 120 to maintain the cooling fluid above the ambient temperature.

The thermoelectric cooling unit 120 may include a cold end at which heat from the cooling fluid is withdrawn to cool the cooling fluid and a hot end at which thermoelectric waste heat from the thermoelectric cooling unit 120 is collected. The ambient temperature sensor may be located to measure ambient temperature near the cold end. Thus, the ambient temperature sensor may take a measurement of the ambient air in an area in which the ambient temperature is likely to be the lowest, and therefore an area in which water condensation is likely to occur.

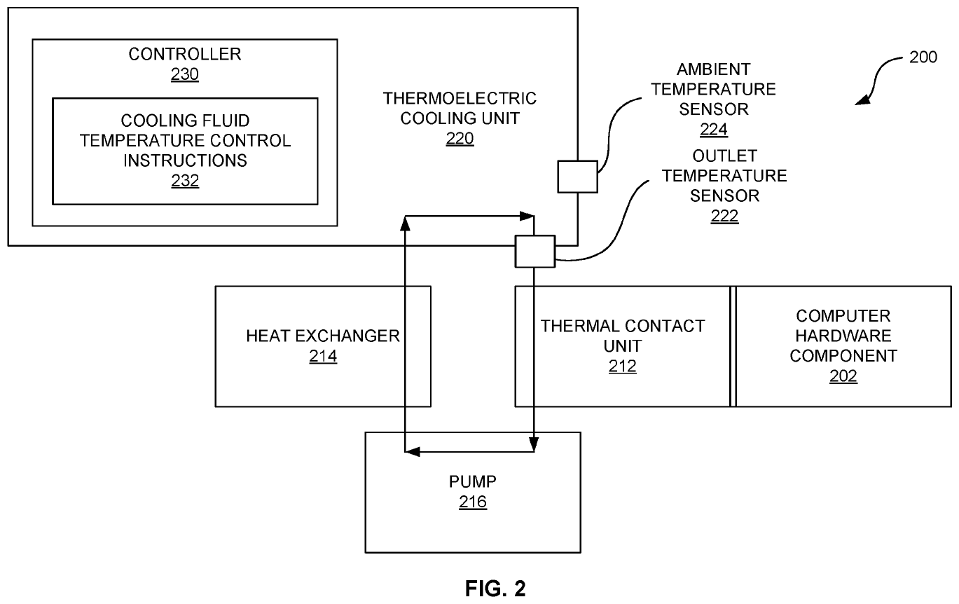

FIG. 2 is a schematic diagram of an example liquid cooling system 200 which includes a thermoelectric cooling device or unit 220 to cool a cooling fluid. The cooling fluid is part of a cooling fluid circulation system to cool a computer hardware component 202 of a computer. The cooling fluid circulation system may be similar to the cooling fluid circulation system 110 of FIG. 1. Further, as with the cooling fluid circulation system 110 of FIG. 1, the computer hardware component 202 cooled by the liquid cooling system 200 may be part of any type of computing device which may employ a liquid cooling system to cool the computer hardware component, such as a desktop computer, laptop computer, or server computer.

The liquid cooling system 200 includes a thermal contact unit 212 cooled by a cooling fluid. The thermal contact unit 212 is able to contact a computer hardware component 202 of the computer to cool the computer hardware component 202. The liquid cooling system 200 further includes a heat exchanger 214 to vent heat from the cooling fluid outside the computer. The liquid cooling system 200 further includes a pump 216 to circulate the cooling fluid between the thermal contact unit 212 and the heat exchanger 214 and to other components.

The liquid cooling system 200 further includes a thermoelectric cooling unit 220 to cool the cooling fluid. The thermoelectric cooling unit 220 may be similar to the thermoelectric cooling unit 120 of FIG. 1, and thus for further description of the thermoelectric cooling unit 220, the description of the thermoelectric cooling unit 120 of FIG. 1 may be referenced.

The thermoelectric cooling unit 220 includes an outlet temperature sensor 222 to detect an outlet temperature of the cooling fluid cooled by the thermoelectric cooling unit 220. The thermoelectric cooling unit 220 further includes an ambient temperature sensor 224 to detect ambient temperature inside the computer. The thermoelectric cooling unit 220 further includes a controller 230 to execute cooling fluid temperature control instructions 232 to control the thermoelectric cooling unit 220 to cool the cooling fluid to a cooling temperature not lower than the ambient temperature, or in other words, to maintain the outlet temperature of the cooling fluid above the ambient temperature.

The thermoelectric cooling unit 220 may be situated between the heat exchanger 214 and the thermal contact unit 212 to cool the cooling fluid after passing through the heat exchanger 214. In other words, the heat exchanger 214 may vent heat from the cooling fluid outside the computer prior to the cooling fluid being cooled by the thermoelectric cooling unit 220.

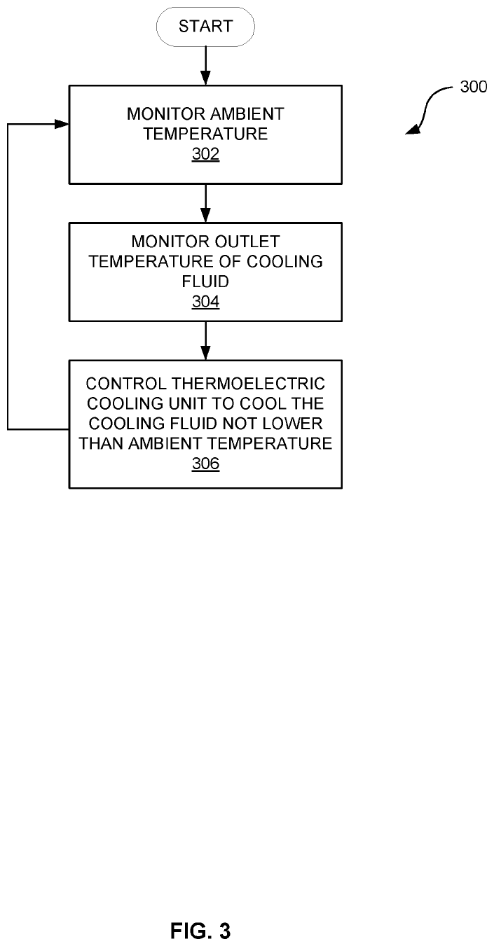

FIG. 3 is a flowchart of an example method 300 for cooling a cooling fluid of a liquid cooling system with a thermoelectric cooling unit. The liquid cooling system is to cool a hardware component of a computer. The method 300 may be executed by a system or device to thermoelectrically cool a cooling fluid as discussed herein, such as the device 100 of FIG. 1 or the liquid cooling system 200 of FIG. 2. The method 300 may be embodied in a non-transitory machine-readable storage medium executable by a processor of a computing device to execute the method 300. For example, the method 300 may be similar to a method executed according to the cooling fluid temperature control instructions 132 of FIG. 1 or a method executed according to the cooling fluid temperature control instructions 232 of FIG. 2.

At block 302, ambient temperature is monitored. Ambient temperature may be monitored inside the computer. Further, the thermoelectric cooling unit may include a cold end and a hot end, and the ambient temperature may be monitored near the cold end, where water condensation may be likely.

At block 304, outlet temperature of a cooling fluid is monitored. Outlet temperature may be measured where the temperature of the cooling fluid is likely to be at its lowest, such as at the outlet of the thermoelectric cooling unit.

At block 306, the thermoelectric cooling unit is controlled to cool the cooling fluid to a temperature not lower than the ambient temperature. The thermoelectric cooling unit may be controlled by turning on, turning off, throttling, increasing the power to, decreasing the power to, or otherwise control the thermoelectric cooling unit to control the temperature to which the cooling fluid is cooled. Thus, the cooling fluid is maintained above ambient temperature, and the likelihood that condensation forms inside the computer as a result of the thermoelectric cooling may be reduced.

The method 300 may be repeated periodically. The method 300 may be a continuous process that is periodically executed while the liquid cooling system is in operation. Further, the blocks of the method 300 need not be performed in the exact sequence shown. For example, the outlet temperature of the cooling fluid may be monitored before, or in parallel with, monitoring of the ambient temperature.

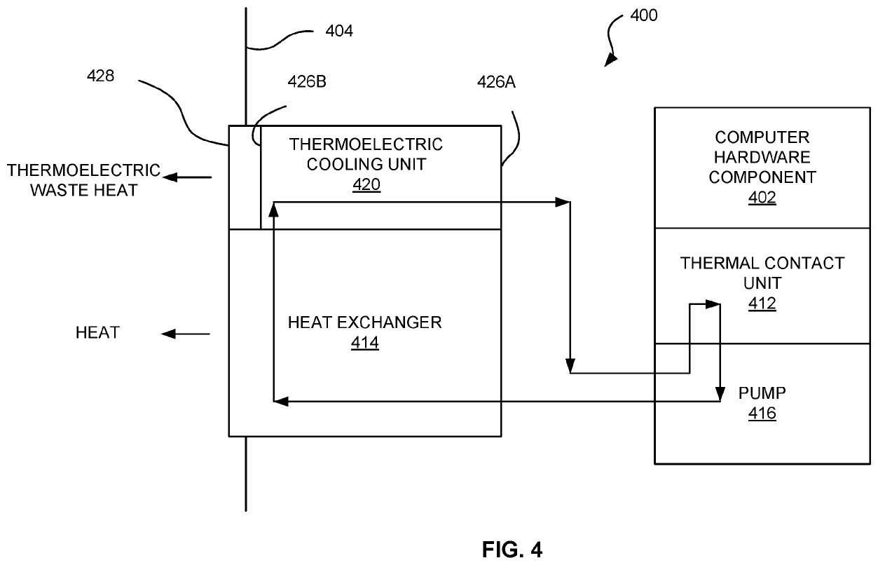

FIG. 4 is a schematic diagram of an example liquid cooling system 400 depicted inside a housing of a computer. The liquid cooling system 400 may be similar to the liquid cooling system 200 of FIG. 2, with like elements numbered in the “400” series rather than the “200” series, and thus includes a thermal contact unit 412, a heat exchanger 414, a pump 416, and a thermoelectric cooling unit 420 to cool a cooling fluid for cooling a computer hardware component 402. For further description of these elements, the description of the liquid cooling system 200 of FIG. 2 may be referenced.

The liquid cooling system 400 is located inside a housing or case of the computer. The heat exchanger 414 and thermoelectric cooling unit 420 are located adjacent to a housing wall 404 of the computer and are each able to vent heat past the housing wall 404 outside of the computer. The thermoelectric cooling unit 420 includes a separate heat exchanger 428 to vent thermoelectric waste heat from the thermoelectric cooling unit 420 outside the computer.

In some examples, each of the heat exchanger 414 and thermoelectric cooling unit 420 may be separately fixed to the housing wall 404. In other examples, one of the heat exchanger 414 and thermoelectric cooling unit 420 may be fixed to the housing wall, and the heat exchanger 414 and the thermoelectric cooling unit 420 may be fixed to one another.

Further, the thermoelectric cooling unit 420 includes a cold end 426A to cool the cooling fluid and a hot end 426B at which thermoelectric waste heat is collected. The separate heat exchanger 428 vents thermoelectric waste heat from the hot end 426B outside of the computer.

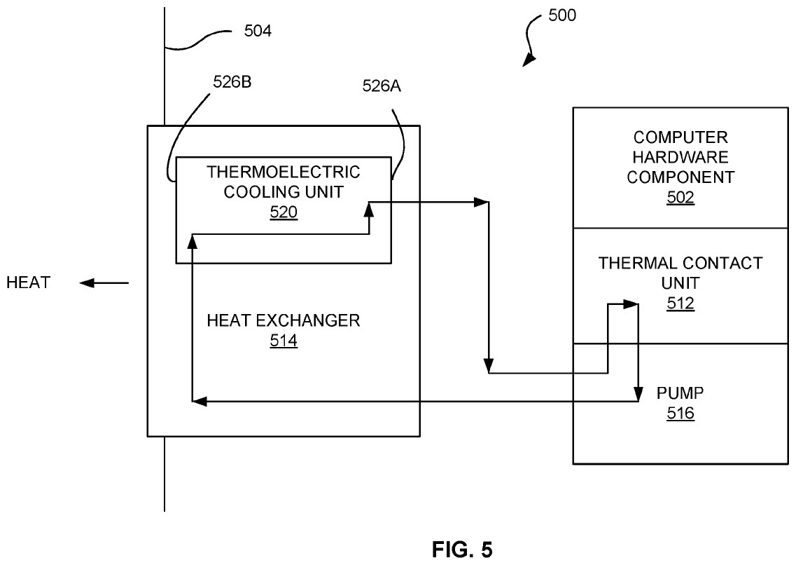

FIG. 5 is a schematic diagram of an example liquid cooling system 500 depicted inside a housing of a computer. The liquid cooling system 500 may be similar to the liquid cooling system 200 of FIG. 2, with like elements numbered in the “500” series rather than the “200” series, and thus includes a thermal contact unit 512, a heat exchanger 514, a pump 516, and a thermoelectric cooling unit 520 to cool a cooling fluid for cooling a computer hardware component 502. For further description of these elements, the description of the liquid cooling system 200 of FIG. 2 may be referenced.

Similar to the liquid cooling system 400 of FIG. 4, the liquid cooling system 500 of FIG. 5 is located inside a housing of the computer. However, the thermoelectric cooling unit 520 is integrated into the heat exchanger 514. The heat exchanger 514 is located adjacent to a housing wall 504 of the computer and is able to vent heat past the housing wall 504 outside the computer. The heat exchanger 514 may be fixed to the housing wall 504.

The thermoelectric cooling unit 520 includes a cold end 526A and hot end 526B. The thermoelectric cooling unit 520 transfers thermoelectric waste heat from the hot end 526B through the heat exchanger 514 and out the computer. For example, the heat exchanger 514 may include an air vent pathway through which heat is vented outside the computer, and the cold end 526A may feed its thermoelectric waste heat into the air vent pathway to be vented from the computer. In other words, the thermoelectric cooling unit 520 and heat exchanger 514 may be integrated with the hot end 526B of the thermoelectric cooling unit 520 located within, or adjacent to, the air vent pathway, to conduct thermoelectric waste heat to the air vent pathway to be vented from the computer.

Thus, a liquid cooling system to cool a computer hardware component may be provided which includes a thermoelectric cooling unit for improved cooling performance. The thermoelectric cooling unit may be controlled to cool the cooling fluid closer to ambient temperature without dropping below ambient temperature, thereby reducing the risk of water condensation.

It should be recognized that features and aspects of the various examples provided above can be combined into further examples that also fall within the scope of the present disclosure. The scope of the claims should not be limited by the above examples but should be given the broadest interpretation consistent with the description as a whole.

1. A device comprising:
a cooling fluid circulation system to circulate a cooling fluid to cool a hardware component of a computer;
a thermoelectric cooling unit to cool the cooling fluid; and
a controller to execute temperature control instructions to control the thermoelectric cooling unit to cool the cooling fluid to a cooling temperature not lower than ambient temperature.

2. The device of claim 1, wherein the cooling fluid circulation system includes a heat exchanger to vent heat from the cooling fluid outside the computer, and the cooling fluid circulation system is to circulate the cooling fluid from the heat exchanger to the thermoelectric cooling unit for cooling prior to circulation to the hardware component.

3. The device of claim 2, wherein the thermoelectric cooling unit is fixed to the heat exchanger.

4. The device of claim 1, wherein:
the thermoelectric cooling unit includes an outlet through which cooled cooling fluid leaves the thermoelectric cooling unit;
the device further comprises an outlet temperature sensor located at the outlet to measure an outlet temperature of the cooling fluid; and
the controller is to control the thermoelectric cooling unit to maintain the outlet temperature of the cooling fluid above the ambient temperature.

5. The device of claim 1, wherein the device further comprises an ambient temperature sensor located near the thermoelectric cooling unit to measure the ambient temperature near the thermoelectric cooling unit.

6. The device of claim 5, wherein the thermoelectric cooling unit includes a cold end at which heat from the cooling fluid is withdrawn to cool the cooling fluid, and the ambient temperature sensor is to measure ambient temperature near the cold end.

7. A thermoelectric cooling device comprising:
a thermoelectric cooling unit to cool a cooling fluid of a cooling fluid circulation system of a computer, the cooling fluid circulation system to circulate a cooling fluid to cool a hardware component of the computer;
an outlet temperature sensor to detect an outlet temperature of the cooling fluid at an outlet of the thermoelectric cooling unit;
an ambient temperature sensor to detect ambient temperature inside the computer; and
a controller to execute cooling fluid temperature control instructions to control the thermoelectric cooling unit to cool the cooling fluid to a cooling temperature not lower than the ambient temperature.

8. The thermoelectric cooling device of claim 7, further comprising a heat exchanger to vent heat from the cooling fluid outside the computer prior to the cooling fluid being cooled by the thermoelectric cooling unit.

9. The thermoelectric cooling device of claim 7, wherein the thermoelectric cooling unit includes a cold end to cool the cooling fluid, and the ambient temperature sensor is to measure ambient temperature near the cold end.

10. The thermoelectric cooling device of claim 7, further comprising a heat exchanger to vent heat from the cooling fluid outside the computer, the heat exchanger integrated with the thermoelectric cooling unit to vent thermoelectric waste heat from the thermoelectric cooling unit outside the computer.

11. A liquid cooling system comprising:
a thermal contact unit cooled by a cooling fluid, the thermal contact unit to contact a computer hardware component of a computer to cool the computer hardware component;
a heat exchanger to vent heat from the cooling fluid outside the computer;
a pump to circulate the cooling fluid between the thermal contact unit and the heat exchanger; and
a thermoelectric cooling unit to cool the cooling fluid, the thermoelectric cooling unit including an outlet temperature sensor to detect an outlet temperature of the cooling fluid cooled by the thermoelectric cooling unit, an ambient temperature sensor to detect ambient temperature inside the computer, and a controller to execute cooling fluid temperature control instructions to control the thermoelectric cooling unit to maintain the outlet temperature of the cooling fluid above the ambient temperature.

12. The liquid cooling system of claim 11, wherein the thermoelectric cooling unit is situated between the heat exchanger and the thermal contact unit to cool the cooling fluid after passing through the heat exchanger.

13. The liquid cooling system of claim 11, wherein the thermoelectric cooling unit includes a cold end to cool the cooling fluid, and the ambient temperature sensor is located to measure ambient air near the cold end.

14. The liquid cooling system of claim 11, wherein the thermoelectric cooling unit includes a separate heat exchanger to vent thermoelectric waste heat from the thermoelectric cooling unit outside the computer.

15. The liquid cooling system of claim 11, wherein:
the heat exchanger includes an air vent pathway through which heat is vented outside the computer; and
the thermoelectric cooling unit is to feed thermoelectric waste heat into the air vent pathway.
